(19) United States
(12) Patent Application Publication
(10) Pub. No.: US 2021/0141214 A1
(43) Pub. Date: May 13, 2021

(54) OUT-OF-PLANE MOTION MOTOR FOR CARRYING REFLECTOR AND MANUFACTURING METHOD THEREOF

(71) Applicant: Innovative Interface Laboratory Corp., Hsinchu (TW)

(72) Inventor: Yu-Wen HSU, Taipei (TW)

(21) Appl. No.: 17/091,030

(22) Filed: Nov. 6, 2020

Related U.S. Application Data
(60) Provisional application No. 62/931,926, filed on Nov. 7, 2019.

(51) Int. Cl. G02B 26/08; B81B 3/00; G02B 26/00

(52) U.S. Cl. CPC G02B 26/0833; B81B 2201/034; G02B 26/001; B81B 3/0067

(57) ABSTRACT

A reflector device is provided in the present disclosure, and includes a base, a first single-axis motion motor, a fulcrum structure and a reflector. The base includes a base plate having a base plate surface. The first single-axis motion motor is disposed on the base plate surface, and has a motion direction parallel to a normal direction of the base plate surface. The fulcrum structure is disposed on the base plate surface. The reflector has a first and a second ends connected with the first single-axis motion motor and the fulcrum structure respectively.

### CROSS-REFERENCE TO RELATED APPLICATION AND CLAIM OF PRIORITY

This application claims the benefit of U.S. Provisional Applications No. 62/931,926, filed on Nov. 7, 2019 in the United States Patent and Trademark Office, the disclosures of which are incorporated herein in their entirety by reference.

### FIELD OF THE INVENTION

The invention is related to an out-of-plane motion motor, and more particularly to a device using a micro actuator and manufacturing method thereof.

### BACKGROUND OF THE INVENTION

In order to achieve the effect of changing the reflection direction and angle of traditional light reflecting devices, especially those with a small size, such as mirrors in the order of millimeters or less, piezoelectric materials are usually used to tilt the mirror. However, the deformation of the piezoelectric material is limited and the displacement distance is also limited. Therefore, it is usually necessary to enlarge the displacement distance through the magnifying mechanism as shown in FIG. 15. However, the disadvantage is that the setting of the magnifying mechanism increases the complexity of the entire device and the failure rate. In addition, although the displacement of the piezoelectric material is amplified, the load generated by the reflector is also amplified. Furthermore, the arrangement of the magnifying mechanism also increases the volume of the overall device. Moreover, the response of the piezoelectric material is slow and cannot be adapted to devices that require rapid tilting of the mirror.

The alternative way is to replace piezoelectric materials with micro-electro-mechanical systems (MEMS) to tilt the light reflecting device. However, the out-of-plane movement and tilt angle that the micro-electro-mechanical system can achieve is very small, unless adopting a leverage system for tilt angle enlargement purpose. This generally causes chip size being dozen times of reflector size and this also causes the overall device structure to become complicated, larger, and causes problems such as a decrease in manufacturing yield rate and a tendency to easily wear out from use. Therefore, an epoch-making invention is urgently needed to surpass the above-mentioned conventional technologies in the field of micro-reflectors.

### SUMMARY OF THE INVENTION

In order to increase the displacement distance of the out-of-plane motion mechanism, reduce the complexity of the out-of-plane motion mechanism, reduce the failure rate, and improve the manufacturing yield rate, the out-of-plane motion motor and the manufacturing method provided by the present invention can achieve a larger displacement distance than traditionally used piezoelectric materials, or a more solid, sturdy, simple and reliable out-of-plane motion motor than the overall structure of a traditional planar motion motor that converts horizontal motion to vertical motion through a conversion mechanism. Taking the reflector as an example, if applied to a scanner, the out-of-plane motion motor disclosed in the present invention can provide a wider scanning angle and a faster angle conversion.

In accordance with an aspect of the present invention, a reflector device is provided. The reflector device comprises a base, a first single-axis motion motor, a fulcrum structure and a reflector. The base includes a base plate having a base plate surface. The first single-axis motion motor is disposed on the base plate surface, and has a motion direction parallel to a normal direction of the base plate surface. The fulcrum structure is disposed on the base plate surface. The reflector has a first and a second ends connected with the first single-axis motion motor and the fulcrum structure respectively.

In accordance with a further aspect of the present invention, a reflector device is provided. The reflector device comprises a base, a plurality of single-axis motion motors and a reflector. The base comprises a base plate having a base plate surface. The plurality of single-axis motion motors is disposed on the base plate surface, and has a motion direction parallel to a normal direction of the base plate surface. The reflector is connected to the plurality of single-axis motion motors such that the reflector has a translational direction and two rotational directions.

In accordance with another aspect of the present invention, an out-of-plane motion motor for carrying a reflector is provided. The out-of-plane motion motor for carrying a reflector comprises a base and a first single-axis motion motor. The base has a normal direction. The first single-axis motion motor is fixed to the base, has a motion direction parallel to the normal direction, and includes a single-axis actuator configured to carry and move the reflector.

### BRIEF DESCRIPTION OF THE DRAWINGS

The details and advantages of the present invention will become more readily apparent to those ordinarily skilled in the art after reviewing the following detailed descriptions and accompanying drawings.

FIG. 1 shows a top view of an embodiment of an out-of-plane motion motor of the present invention.

FIG. 2 is a schematic diagram showing a sectional side view of the out-of-plane motion motor along the secant line A-A′ in FIG. 1.

FIG. 3 shows a top view of another embodiment of the out-of-plane motion motor of the present invention.

FIG. 4 is a three dimensional diagram showing the out-of-plane motion motor shown in FIG. 3.

FIG. 5 is a schematic diagram showing a single-axis actuator of the present invention.

FIG. 6 is a partial schematic diagram showing a single-axis actuator wafer of the present invention.

FIG. 7 shows an exploded view of an out-of-plane motion actuator of the present invention.

FIG. 8 is a three dimensional diagram showing the out-of-plane motion actuator of the present invention.

FIG. 9 is a schematic diagram showing an embodiment of a single-sided single-axis actuator of the present invention.

FIG. 10 is a schematic diagram showing an actuation of the single-sided single-axis actuator of the present invention.

FIG. 11 is a schematic diagram showing an embodiment of a double-sided single-axis actuator of the present invention.

FIG. 12 is a schematic diagram showing an actuation of the double-sided single-axis actuator of the present invention.

FIG. 13 is a schematic diagram showing another actuation of the double-sided single-axis actuator of the present invention.

FIG. 14 is a schematic diagram showing another actuation of the double-sided single-axis actuator of the present invention; and

FIG. 15 is a planar schematic diagram showing a displacement magnifying mechanism of the present invention.

### DETAILED DESCRIPTION OF THE PREFERRED EMBODIMENT

The present invention will now be described more specifically with reference to the following embodiments. It is to be noted that the following descriptions of the preferred embodiments of this invention are presented herein for the purposes of illustration and description only; they are not intended to be exhaustive or to be limited to the precise form disclosed.

Please refer to FIG. 1 and FIG. 2, wherein FIG. 1 shows a top view of an out-of-plane motion motor of an embodiment of the present invention, and FIG. 2 is a schematic diagram showing a sectional side view of the out-of-plane motion motor along the secant line A-A′ in FIG. 1. FIG. 1 and FIG. 2 show that a first single-axis motion motor 7045-1 and a second single-axis motion motor 7045-2 are configured on a base plate surface 852 of a base plate 851 of the out-of-plane motion motor 7040. The out-of-plane motion motor 7040 serves as a mechanism that can produce a planar motion; and a motion direction of an actuating end 855 of a single-axis actuator 854 is substantially parallel to a normal direction of the base plate surface 852. The normal direction for FIG. 1 is a direction that is perpendicular to the drawing surface, and the normal direction for FIG. 2 is an upward direction. A reflector 5000′ is carried on the actuating end 855 of a single-axis actuator 854 in the single-axis motion motor 7045-1, wherein the reflector 5000′ can be a reflector, a reflecting mirror, a lens, a semi-reflecting mirror, etc., or a combination of any of two or more than two. Because of the high-speed response performance of a micro-electromechanical system, the reflector 5000′ of the present invention can also be a vibrating membrane. According to the configuration locations of the first single-axis motion motor 7045-1 and the second single-axis motion motor 7045-2, the reflector 5000′ can not only be moved upwards and downwards in parallel, but also can be rolled. Therefore, the reflector 5000′ can have an additional displacement in the out-of-plane direction caused by the single-axis motion motors 7045-1 and 7045-2 of the present invention. In addition, because there is usually no need for other structures underneath the reflector 5000′ to support the reflector 5000′, a redundant space 852′ is formed between the reflector 5000′ and the base plate surface 852, where the electronic element 6009 can be configured therein to save the overall equipment space. In addition, in order to facilitate the handling of the out-of-plane motion motor 7040, a base plate frame 853 is formed on the periphery of the base plate 851 in a direction substantially parallel to the direction of the normal line of the base plate surface 852. That is, the periphery of the base plate 851 is thickened to facilitate the handling by a robotic arm (figure not shown).

Please refer to FIG. 3 and FIG. 4, wherein FIG. 3 shows a top view of the out-of-plane motion motor according to another embodiment of the present invention, and FIG. 4 is a three dimensional diagram showing the out-of-plane motion motor shown in FIG. 3. It can be seen in FIG. 3 and FIG. 4 that two single-axis motion motors 7045-1 and 7045-2 are no longer only configured on both sides on the base plate surface 852, but additional single-axis motion motors are further cooperatively configured on the four corners on the base plate surface 852, which include a first single-axis motion motor 7045-1, a second single-axis motion motor 7045-2, a third single-axis motion motor 7045-3 and a fourth single-axis motion motor 7045-4, and these four single-axis motion motors form the out-of-plane motion motor 7040′ according to another embodiment of the present invention. Therefore, in the embodiment shown in FIG. 3 and FIG. 4, the reflector 5000′ can not only be moved upwards and downwards and parallel to the normal direction of the base plate surface 852, but also have pitching motion by synchronously controlling the first single-axis motion motor 7045-1 and the second single-axis motion motor 7045-2 and/or synchronously controlling the third single-axis motion motor 7045-3 and the fourth single-axis motion motor 7045-4. Alternatively, the reflector 5000′ can also have a rolling motion by synchronously controlling the first single-axis motion motor 7045-1 and the fourth single-axis motion motor 7045-4 and/or synchronously controlling the third single-axis motion motor 7045-3 and the second single-axis motion motor 7045-2. Thus the reflector 5000′ totally has three degrees-of-freedom. Specifically, the four single-axis motion motors can be controlled to generate different displacements respectively, so that the reflector 5000′ can have translational, rolled and pitched motions. The number and the configuration locations of the single-axis motion motors in FIG. 3 and FIG. 4 are not absolute, and can be altered according to actual demands. For example, because three points can form a plane, in theory, only three single-axis motion motors are needed to achieve three degrees-of-freedom movements, i.e. translation of up-and-down and rotations of roll and pitch.

Please refer to FIG. 5, which is a schematic diagram showing a main structure of a single-axis motion motor according to one embodiment of the present invention, wherein the main structure of the single-axis motion motor includes a single-axis actuator 854, and its detail structure is showed in FIG. 5, a wafer substrate is used as the last bottom structure. The single-axis actuator 854 mainly includes a movable electrode structure 500 on the wafer substrate 20000′ and fixed electrode structures including a first fixed electrode structure 300 and a second fixed electrode structure 610. The movable electrode structure 500 has a keel 510 and comb fingers 520 fixed on the keel 510, and the first fixed electrode structure 300 has comb fingers 320 fixed on a supporting arm 1200. A sensing capacitor 600 including the second fixed electrode structure 610 and the movable electrode structure 500 is formed for sensing a capacitance value therebetween, and a distance between the movable electrode structure 500 and the first fixed electrode structure 300 is obtained through the conversion of the measured capacitance value. The first fixed electrode structure 300 is indirectly fixed on the wafer substrate 20000′ by a third anchor 803 through the supporting arm 1200, and the second fixed electrode structure 610 is fixed on the wafer substrate 20000′ by a fourth anchor 804. The movable electrode structure 500 is indirectly fixed on the wafer substrate 20000′ by a second anchor 802 through two constraining hinges 900 which can prevent the movement of the movable electrode structure 500 from exceeding the allowable range. An embodiment of the actuating end 855 is a T-bar 1100, wherein the T-bar 1100 is fixed on the movable electrode structure 500, and is indirectly fixed by a first anchor 801 through two main hinges 400. A first center point 450 is formed between the T-bar 1100 and the main hinges 400 at the two sides of the T-bar 1100. The main hinges 400 are used to support most of the weight of the T-bar 1100 and the weight of the movable electrode structure 500, and bear an elastic restoring force caused by returning the T-bar 1100 when the electrostatic force between the movable electrode structure 500 and the first fixed electrode structure 300 disappears. In order to avoid the T-bar 1100 and the reflector 5000′ from separating by a lateral force applied to the T-bar 1100 or the reflector 5000′, a fulcrum hinge 700 is configured on a vertical portion of the T-bar 1100. The fulcrum hinge 700 can deform laterally to absorb the aforementioned lateral force (i.e., in the X direction in FIG. 5). In addition, in order to maintain a parallelism of a head portion of the T-bar 1100, i.e. the parallelism between the T-bar 1100 and the base plate surface 852, the fulcrum hinge 700 can be designed to have no deformation under forces applied in the normal direction (in the Y direction in FIG. 5) of the base plate surface 852.

Please refer to FIG. 6, which is a partial schematic diagram showing an actuator wafer of the present invention. The actuator wafer 20000 includes a plurality of single-axis actuating structures. FIG. 6 shows a portion of an actuator wafer 20000 containing one single-axis actuator structure 10000. After the single-axis actuator structure 10000 is cut from the actuator wafer 20000, the single-axis actuator 854 is obtained as shown in FIG. 5. The single-axis actuating structure 10000 of the micro-electromechanical system is manufactured by using the semiconductor process technique, which can form a plurality of the single-axis actuators on a piece of the actuator wafer 20000, and then the actuator wafer 20000 is cut into the plurality of the single-axis actuators. In order to avoid the trouble caused by process residues and debris, a cavity 200 is formed below the comb fingers 520 of the movable electrode structure 500 and the comb fingers 320 of the first fixed electrode structure 300 in the present invention, so that the residues and debris can be discharged from the cavity 200 or can be at least settled in the cavity 200 to keep away from each fingers. For the same reason, a third cavity 20500 is formed under the T-bar 1100 to facilitate the discharge of the residues and debris generated by the manufacturing process under the T-bar 1100.

Please refer to FIG. 7 and FIG. 8, wherein FIG. 7 shows an exploded view of an out-of-plane motion motor of the present invention, and FIG. 8 is a three dimensional diagram showing the out-of-plane motion motor of the present invention. FIG. 7 and FIG. 8 show that the single-axis actuating structure 10000 and the wafer substrate 20000′ in FIG. 6 is cut to form a single-axis actuator 854, and then the single-axis actuator 854 is configured on a circuit board 6001 to form a single-axis motion motor 7045. In FIGS. 5, 7 and 8, it can be seen that the single-axis actuator 854 includes a substrate 100, to which the actuating end 855, the first anchor 801, the second anchor 802, the third anchor 803 and the fourth anchor 804 are connected. A control chip 6008 can be further configured on the circuit board 6001 and be adjacent to the single-axis actuating structure 10000 to control the single-axis actuating structure 10000 nearby. The control chip 6008 can be made while the wafer 20000 (please refer to FIG. 6) is in the production stage (not shown), and is cut together with the single-axis actuating structure 10000, and then both are configured on the circuit board 6001 together. If the control chip 6008 and the single-axis actuating structure 10000 are made on the same wafer 20000, both are connected together by the wafer substrate 20000′. The circuit board 6001 is fixed on the base plate 6003 by clamps 6004. Contact pads 6006 of the circuit board 6001 are electrically connected to metal pads 6007 on the base plate surface 6005, causing the electronic signal to be transmitted to the control chip 6008 and each of the comb fingers 520, 320 through the contact pads 6006, the metal pads 6007 and the circuit in the circuit board 6001 (figure not shown) to form a complete route of the electronic signal for the out-of-plane motion actuator 6000. According to requirements, other electrical connection pads 6007′ can be further configured on the base plate surface 6005 to electrically connect to other electronic elements (figure not shown). The metal pads 6007 and the electrical connection pads 6007′ have, but are not limited to, a one-to-one correspondence relationship therebetween. For the circuit board 6001, the metal pads 6007 or the electrical connection pads 6007′ can be used, that is, the location of the circuit board 6001 can be determined according to the actual demand, such as a size of the reflector 5000′. In addition, the actuator terminal 855 forms a T-bar 1100 with a T shape; the area used to bear an object (for example, the reflector 5000′ in FIG. 2) is enlarged by a top of the horizontal T-bar 1100.

Please refer to FIG. 9 and FIG. 10, wherein FIG. 9 is a schematic diagram showing a motion motor having only one single-axis actuator (or called a single-sided single-axis-actuator motion motor) according to an embodiment of the present invention, and FIG. 10 is a schematic diagram showing an actuation of the single-sided single-axis-actuator motion motor of the present invention. FIG. 9 and FIG. 10 show that one side of the single-sided single-axis-actuator motion motor 8000 is a fulcrum structure 7000, and the opposite side of the single-sided single-axis-actuator motor 8000 is the single-axis motion motor 7045 of the present invention. Therefore, the fulcrum structure 7000 and the single-axis motion motor 7045 are just located at two ends of the reflector 5000′ respectively. They are usually located at left-right terminals or front-rear terminals of the reflector 5000′, or can also be arranged at two terminals of the diagonal of the reflector 5000′ respectively. Only a slight rotation of the reflector 5000′ is allowed on the fulcrum structure 7000. The fulcrum structure 7000 usually has, but is not limited to, a structure such as the fulcrum hinge 700 (as shown in FIG. 5) to absorb a shear stress caused by improper external forces. When the single-axis motion motor 7045 moves upwards or downwards, the location of the reflector 5000′ connected thereto is also moved upwards or downwards along with the single-axis motion motor 7045. FIG. 10 shows the location and posture of the reflector 5000′ connected to the single-axis motion motor 7045 while the single-axis motion motor 7045 moves upwards to a top dead center (TDC) or downwards to a bottom dead center (BDC). Furthermore, in order to protect the reflector 5000′, a protective structure 5000″ mounted above the reflector 5000′ is provided in the present invention. The protective structure 5000″ is usually supported by a supporting wall 9002 of an accommodating base 9000. The single-sided single-axis out-of-plane motion motor 7040 (figure not shown) is configured on the accommodating bottom plate 9001 of the accommodating base 900. The four single-axis out-of-plane motion motors 7040′ in FIGS. 3 and 4 and dual side single-axis out-of-plane motion motor 7040 in FIGS. 1 and 2 can be configured on the accommodating bottom plate 901 to obtain protection of the protecting structure 5000″.

Please refer to FIG. 11, FIG. 12 and FIG. 13, wherein FIG. 11 is a schematic diagram showing an embodiment of a two-sided single-axis-actuator motion motor of the present invention, FIG. 12 is a schematic diagram showing the two-sided single-axis-actuator motion motor of the present invention, and FIG. 13 is a schematic diagram showing another actuation of the two-sided single-axis-actuator motion motor of the present invention. FIG. 11, FIG. 12 and FIG. 13 show that one side of the two-sided single-axis-actuator motion motor 9000 is the first single-axis motion motor 7045-1 of the present invention, and the opposite side of the two-sided single-axis-actuator motor 9000 is the second single-axis motion motor 7045-2 of the present invention. FIG. 12 shows the locations of the two ends of the reflector 5000′ respectively connected to the first single-axis motion motor 7045-1 and the second single-axis motion motor 7045-2 while the first single-axis motion motor 7045 moves up to its top dead center, and the second single-axis motion motor 7045-2 moves down to its bottom dead center at the same time. Contrary to FIG. 12, FIG. 13 shows the locations of the two ends of the reflector 5000′ respectively connected to the first single-axis motion motor 7045-1 and the second single-axis motion motor 7045-2 while the first single-axis motion motor 7045 moves down to its bottom dead center, and the second single-axis motion motor 7045-2 moves up to its top dead center at the same time. However, in the implementation state of some actuators, they can only move upwards or downwards, and then return to their original relatively low or relatively high locations. If the embodiments shown in FIG. 12 and FIG. 13 are understood as the actuator that can only move upwards, it can be understood according to FIG. 12 that the second single-axis motion motor 7045-2 remains stationary, while the first single-axis motion motor 7045-1 moves upwards, for example, to its top dead center. In contrast, it can be understood according to FIG. 13 that the first single-axis motion motor 7045-1 remains stationary, while the second single-axis motion motor 7045-2 moves upwards. Similarly, if the embodiments shown in FIG. 12 and FIG. 13 are understood as the actuator that can only move downwards, it can be understood according to FIG. 12 that the first single-axis motion motor 7045-1 remains stationary, while the second single-axis motion motor 7045-2 moves downwards, for example, to its bottom dead center. In contrast, it can be understood according to FIG. 13 that the second single-axis motion motor 7045-2 remains stationary, while the first single-axis motion motor 7045-1 moves downwards.

Please refer to FIG. 14, which is a schematic diagram showing another actuation of the double-sided single-axis actuator of the present invention. When the double-sided single-axis actuator of the out-of plane motion motor 7040 can only move upwards or downwards, the out-of plane motion motor 7040 in the present invention can still achieve both translational and rolling movement according to the difference of the moving amplitude of the two actuators. Please see the two downward hollow arrows in FIG. 14, when the first single-axis motion motor 7045-1 and the second single-axis motion motor 7045-2 can only move downwards, the downward movement amount of the first single-axis motion motor 7045-1 is larger, and the downward movement amount of the second single-axis motion motor 7045-2 is smaller. Similarly, please see the two upward hollow arrows in FIG. 14, when the first single-axis motion motor 7045-1 and the second single-axis motion motor 7045-2 can only move upwards, the upward movement amount of the first single-axis motion motor 7045-1 is smaller, and the upward movement amount of the second single-axis motion motor 7045-2 is larger. It can be seen that through the installation of two or more single-axis motion motors 7045, the reflector provided in the present invention can achieve both up and down translation and simultaneous tilting actions and postures. Not only can the angle of the reflector be changed, but also the size of the image presented by reflected electromagnetic waves (such as visible light).

Please refer to FIG. 15, which is a planar schematic diagram showing a displacement magnifying mechanism of the present invention. In order to increase the moving distance, a displacement magnifying mechanism 4000 can be used in the present invention. The displacement magnifying mechanism 4000 of the present invention includes a first lever L1 and a second lever L2, wherein an end of the first lever L1 is a first lever fulcrum L1f, and the other end of the first lever L1 is connected to the second lever L2 through a second contact point L2c. The point of application of the out-of-plane motion actuator 6000 is at a first contact point L1c. Because the first contact point L1c is located between the first lever fulcrum L1f and the second contact point L2c, the moving amplitude of the second contact point L2c is larger than that of the first contact point L1c, when the out-of-plane motion actuator 6000 moves. Similarly, because the second contact point L2c is located between a second lever fulcrum L2f and a carrying point L2m, the moving amplitude of the carrying point L2m is larger than that of the second contact point L2c, when the second contact point L2c moves. Therefore, the displacement of the out-of-plane motion actuator 6000 can be magnified, so that the displacement of the reflector 5000′ is larger than that of the out-of-plane motion actuator 6000. If a more significant amplification effect is desired, a first distance a is smaller than a second distance b, and a third distance c is smaller than a fourth distance d, wherein the first distance a is a distance between the first contact point L1c and the first lever fulcrum L1f, the second distance b is a vertical distance between the first contact point L1c and the second contact point L2c, the third distance c is a distance between the second contact point L2c and the second lever fulcrum L2f, and the fourth distance d is a vertical distance between the second contact point L2c and the carrying point L2m. Accordingly, although the piezoelectric material in the prior art uses a displacement amplifying mechanism to enlarge its moving distance, the original displacement distance of the actuator of the present invention is much greater than that of the piezoelectric material, and thus the overall displacement distance achieved by the present invention is still far greater than the displacement distance of the piezoelectric material after being amplified by the displacement amplifying mechanism.

In summary, firstly, the micro-electromechanical motion motor used in the present invention can be manufactured through a semiconductor process to make mass production more convenient, and secondly, the single-axis motion motor structure is cut from the wafer and then it is arranged vertically on a base plate, so that the traditional movement motor that can only move along the wafer plane can produce an out of plane movement effect. Because under the premise of the same device volume, the MEMS motion motor can obtain a larger displacement distance than the traditionally used piezoelectric material, and the vertical use of the MEMS motion motor in the present invention can make the reflector obtain a greater tilt and angle of rotation. In addition, by a plurality of motion motors, the reflector can move in and out of the plane in parallel, as well as roll and pitch. Furthermore, the out-of-plane motion motor, which is directly completed by the micro-electromechanical motion motor vertically, is indeed more solid, firm, simple and reliable than the overall structure of a traditional planar motion motor that converts a horizontal motion to a vertical motion through a conversion mechanism. Therefore, if applied to a reflector of a scanner, the out-of-plane motion motor provided in the present invention can provide a wider scanning angle and a faster angle conversion. Therefore, the out-of-plane motion motor provided in the present invention can be a great contribution to related industries.

### Embodiments

1. A reflector device comprises a base, a first single-axis motion motor, a fulcrum structure and a reflector. The base includes a base plate having a base plate surface. The first single-axis motion motor is disposed on the base plate surface, and has a motion direction parallel to a normal direction of the base plate surface. The fulcrum structure is disposed on the base plate surface. The reflector has a first and a second ends connected with the first single-axis motion motor and the fulcrum structure respectively.
2. The reflector device according to Embodiment 1, wherein an electronic component is disposed on the base plate surface and below the reflector to control a movement of the reflector.
3. The reflector device according to Embodiment 1 or 2, wherein a fulcrum hinge is further disposed between the reflector and the first single-axis motion motor.
4. The reflector device according to any one of Embodiments 1-3, wherein the fulcrum structure is a second single-axis motion motor configured to cause the reflector to translate in the direction parallel to the normal direction of the base plate surface.
5. The reflector device according to any one of Embodiments 1-4, wherein the first single-axis motion motor includes a substrate forming thereon a single-axis actuator, a comb-shaped driving capacitor and a cavity, the comb-shaped driving capacitor includes a fixed electrode structure fixed to the substrate and a movable electrode structure indirectly connected to the substrate through a main hinge, and a projection of the comb-shaped driving capacitor toward the cavity overlaps the cavity.
6. The reflector device according to any one of Embodiments 1-5, wherein the single-axis motion motor further includes an actuating end formed on the substrate, and the actuating end is connected to and moved by the single-axis actuator to cause the reflector to translate.
7. A reflector device, comprising a base comprising a base plate having a base plate surface; a plurality of single-axis motion motors disposed on the base plate surface, and having a motion direction parallel to a normal direction of the base plate surface; and a reflector connected to the plurality of single-axis motion motors such that the reflector has a translational direction and two rotational directions.
8. The reflector device according to Embodiment 7, further comprising a fulcrum hinge disposed between the reflector and each of the plurality of the single-axis motion motors.
9. The reflector device according to Embodiment 7 or 8, further comprising a protection structure disposed above the reflector.
10. The reflector device according to any one of Embodiments 1-8, wherein the base is placed on an accommodating base having a periphery, and the periphery of the accommodating base has a supporting structure for supporting the protection structure such that the protection structure is suspended above the reflector.
11. An out-of-plane motion motor for carrying a reflector comprises a base and a first single-axis motion motor. The base has a normal direction. The first single-axis motion motor is fixed to the base, has a motion direction parallel to the normal direction, and includes a single-axis actuator configured to carry and move the reflector.
12. The out-of-plane motion motor according to Embodiment 11, further comprising a second single-axis motion motor disposed on the base.
13. The out-of-plane motion motor according to Embodiment 11 or 12, further comprising a second, a third and a fourth single-axis motion motors disposed on the base.
14. The out-of-plane motion motor according to any one of Embodiments 11-13, wherein the first single-axis motion motor further includes a substrate having a control chip.
15. The out-of-plane motion motor according to any one of Embodiments 11-14, wherein the first single-axis motion motor further includes an actuating end actuated by the single-axis actuator and connected to the substrate and the reflector, and the reflector is driven by an electronic component such that the single-axis actuator carries and moves the reflector through the actuating end.
16. The out-of-plane motion motor according to any one of Embodiments 11-15, wherein the substrate has a front surface and a rear surface, and has a cavity penetrating the front and the rear surfaces.
17. The out-of-plane motion motor according to any one of Embodiments 11-16, wherein the actuating end is a T-bar.
18. The out-of-plane motion motor according to any one of Embodiments 11-17, wherein the single-axis actuator further includes a main hinge and a fulcrum hinge, and the T-bar is connected to the base plate via the main hinge and the fulcrum hinge.
19. The out-of-plane motion motor according to any one of Embodiments 11-18, wherein the fulcrum hinge prevents the reflector from peeling off from the T-bar when a shear force is applied to a connecting surface between the reflector and the T-bar.
20. The out-of-plane motion motor according to any one of Embodiments 11-19, wherein the single-axial actuator includes a comb-shaped driving capacitor, and the comb-shaped driving capacitor includes a fixed electrode structure fixed on the substrate and a movable electrode structure connected to the main hinge.

The out-of-plane motion motor provided in the present invention can keep an object at a specific rotation angle, position the object at a specific out-of-plane displacement or be programmed for the object to perform a specific scan trajectory motion. The out-of-plane motion motor also includes a single-axis actuator which allows the out-of-plane linear motion motor to have a large motion stroke. A single tunable spectrum sensing device including the out-of-plane motion motor can satisfy the spectral bandwidth requirement. Therefore, multiple tunable spectrum sensing devices are not needed.

It is contemplated that modifications and combinations will readily occur to those skilled in the art, and these modifications and combinations are within the scope of this invention.

What is claimed is:

1. A reflector device, comprising:
a base including a base plate having a base plate surface;
a first single-axis motion motor disposed on the base plate surface, and having a motion direction parallel to a normal direction of the base plate surface;
a fulcrum structure disposed on the base plate surface; and
a reflector having a first and a second ends connected with the first single-axis motion motor and the fulcrum structure respectively.

2. The reflector device as claimed in claim 1, wherein an electronic component is disposed on the base plate surface and below the reflector to control a movement of the reflector.

3. The reflector device as claimed in claim 1, wherein a fulcrum hinge is further disposed between the reflector and the first single-axis motion motor.

4. The reflector device as claimed in claim 1, wherein the fulcrum structure is a second single-axis motion motor configured to cause the reflector to translate in the direction parallel to the normal direction of the base plate surface.

5. The reflector device as claimed in claim 1, wherein the first single-axis motion motor includes a substrate forming thereon a single-axis actuator, a comb-shaped driving capacitor and a cavity, the comb-shaped driving capacitor includes a fixed electrode structure fixed to the substrate and a movable electrode structure indirectly connected to the substrate through a main hinge, and a projection of the comb-shaped driving capacitor toward the cavity overlaps the cavity.

6. The reflector device as claimed in claim 5, wherein the single-axis motion motor further includes an actuating end formed on the substrate, and the actuating end is connected to and moved by the single-axis actuator to cause the reflector to translate.

7. A reflector device, comprising:
a base comprising a base plate having a base plate surface;
a plurality of single-axis motion motors disposed on the base plate surface, and having a motion direction parallel to a normal direction of the base plate surface; and
a reflector connected to the plurality of single-axis motion motors such that the reflector has a translational direction and two rotational directions.

8. The reflector device as claimed in claim 7, further comprising a fulcrum hinge disposed between the reflector and each of the plurality of the single-axis motion motors.

9. The reflector device as claimed in claim 7, further comprising a protection structure disposed above the reflector.

10. The reflector device as claimed in claim 9 wherein the base is placed on an accommodating base having a periphery, and the periphery of the accommodating base has a supporting structure for supporting the protection structure such that the protection structure is suspended above the reflector.

11. An out-of-plane motion motor for carrying a reflector, comprising:
a base having a noinial direction;
a first single-axis motion motor fixed to the base, having a motion direction parallel to the normal direction, and including a single-axis actuator configured to carry and move the reflector.

12. The motor as claimed in claim 11, further comprising a second single-axis motion motor disposed on the base.

13. The motor as claimed in claim 11, further comprising a second, a third and a fourth single-axis motion motors disposed on the base.

14. The motor as claimed in claim 11, wherein the first single-axis motion motor further includes a substrate having a control chip.

15. The motor as claimed in claim 14, wherein the first single-axis motion motor further includes an actuating end actuated by the single-axis actuator and connected to the substrate and the reflector, and the reflector is driven by an electronic component such that the single-axis actuator carries and moves the reflector through the actuating end.

16. The motor as claimed in claim 14, wherein the substrate has a front surface and a rear surface, and has a cavity penetrating the front and the rear surfaces.

17. The motor as claimed in claim 15, wherein the actuating end is a T-bar.

18. The motor as claimed in claim 17, wherein the single-axis actuator further includes a main hinge and a fulcrum hinge, and the T-bar is connected to the base plate via the main hinge and the fulcrum hinge.

19. The motor as claimed in claim 18, wherein the fulcrum hinge prevents the reflector from peeling off from the T-bar when a shear force is applied to a connecting surface between the reflector and the T-bar.

20. The motor as claimed in claim 18, wherein the single-axial actuator includes a comb-shaped driving capacitor, and the comb-shaped driving capacitor includes a fixed electrode structure fixed on the substrate and a movable electrode structure connected to the main hinge.
